(19) United States
(12) Patent Application Publication
(10) Pub. No.: US 2010/0282314 A1
(43) Pub. Date: Nov. 11, 2010

(54) PHOTOVOLTAIC CELLS AND METHODS TO ENHANCE LIGHT TRAPPING IN SEMICONDUCTOR LAYER STACKS

(75) Inventors: Kevin Michael Coakley, Palo Alto, CA (US); Brad Stimson, Monte Sereno, CA (US); Sam Rosenthal, San Francisco, CA (US)

Correspondence Address: THE SMALL PATENT LAW GROUP LLP, 225 S. MERAMEC, STE. 725T, ST. LOUIS, MO, 63105, US

(73) Assignee: THINSILICION CORPORATION, Mountain View, CA (US)

(21) Appl. No.: 12/762,880

(22) Filed: Apr. 19, 2010

Related U.S. Application Data
(60) Provisional application No. 61/176,072, filed on May 6, 2009.

(51) Int. Cl. H01L 31/00

(52) U.S. Cl. 136/258; 136/261

(57) ABSTRACT

A photovoltaic cell includes a substrate, a semiconductor layer stack, a reflective and conductive electrode layer, and a textured template layer. The semiconductor layer stack is disposed above the substrate. The electrode layer is located between the substrate and the semiconductor layer stack. The template layer is between the substrate and the electrode layer. The template layer includes an undulating upper surface that imparts a predetermined shape to the electrode layer. The electrode layer reflects light back into the semiconductor layer stack based on the predetermined shape of the electrode layer.

### CROSS-REFERENCE TO RELATED APPLICATIONS

This application is a nonprovisional patent application of, and claims priority benefit from, co-pending U.S. Provisional Patent Application Ser. No. 61/176,072, entitled “Photovoltaic Cells And Methods To Enhance Light Trapping In Thin Film Silicon” (the “'072 Application”). The '072 Application was filed on May 6, 2009. The entire disclosure of the '072 Application is incorporated by reference herein in its entirety.

### BACKGROUND OF THE INVENTION

The subject matter described herein relates to photovoltaic devices. Some known photovoltaic devices include thin film solar modules made using thin films of silicon or another semiconductor material. Light that is incident onto the modules passes into the silicon films. If the light is absorbed by the silicon films, the light may generate electrons and holes in the silicon. The electrons and holes are used to create an electric potential and/or an electric current that may be drawn from the modules and applied to an external electric load.

Photons in the light excite electrons in the silicon films and cause the electrons to separate from atoms in the silicon films. In order for the photons to excite the electrons and cause the electrons to separate from the atoms in the films, the photons need an energy that exceeds the energy band gap in the silicon films. The energy of the photons is related to the wavelengths of light that is incident on the films. Therefore, the light that is absorbed by the silicon films is based on the energy band gap of the films and the wavelengths of the light. Light that is absorbed by the films may be referred to as light that is “trapped” by the films.

The amount of electric current or power that is generated by a photovoltaic device may be directly related to the amount of light that is trapped in the silicon films. For example, the efficiency of a photovoltaic device in converting incident light into current can be related to the amount of light or photons that excite electrons in the silicon films of the device. But, some known photovoltaic devices allow a relatively large amount of incident light to pass through the silicon films, reflect off of a reflective electrode, and pass back through the silicon films to exit the device without exciting electrons in the silicon films. The light may pass through the films in a direction that is approximately perpendicular to a substrate below the films and be reflected in an opposite direction.

A need exists for photovoltaic devices that increase the amount of light or photons that is trapped in the semiconductor layers of the devices, or that excite electrons in the semiconductor layers.

### BRIEF DESCRIPTION OF THE INVENTION

In one embodiment, a photovoltaic cell includes a substrate, a semiconductor layer stack, a reflective and conductive electrode layer, and a textured template layer. The semiconductor layer stack is disposed above the substrate. The electrode layer is located between the substrate and the semiconductor layer stack. The template layer is between the substrate and the electrode layer. The template layer includes an undulating upper surface that imparts a predetermined shape to the electrode layer. The electrode layer reflects light back into the semiconductor layer stack based on the predetermined shape of the electrode layer.

In another embodiment, another photovoltaic cell is provided. The photovoltaic cell includes a substrate, a semiconductor layer stack, and an electrode layer. The semiconductor layer stack is disposed above the substrate. The electrode layer is between the substrate and the semiconductor layer stack and includes a reflector layer and a light transmissive conductive layer. The conductive layer includes an undulating upper surface that scatters incident light to the reflector layer. The reflector layer reflects the light back into the semiconductor layer stack after being scattered by the conductive layer.

In another embodiment, another photovoltaic cell is provided. The photovoltaic cell includes a substrate, a semiconductor layer stack, and a reflective and conductive electrode layer. The substrate has a predetermined undulating upper surface. The semiconductor layer stack is disposed above the substrate. The electrode layer is between the upper surface of the substrate and the semiconductor layer stack. The undulating upper surface of the substrate imparts a predetermined shape to the electrode layer. The electrode layer reflects light back into the semiconductor layer stack based on the predetermined shape.

### BRIEF DESCRIPTION OF THE DRAWINGS

FIG. 1 is a perspective view of a schematic diagram of a photovoltaic (PV) device and a detail view of a cross-sectional portion of the PV device according to one embodiment.

FIG. 2 is a cross-sectional view of a PV cell shown in FIG. 1 along line 2-2 in FIG. 1 in accordance with one embodiment.

FIG. 3 illustrates a two dimensional representation of an example of peak structures for a template layer shown in FIG. 1 in accordance with one embodiment.

FIG. 4 illustrates a two dimensional representation of an example of valley structures for a template layer shown in FIG. 1 in accordance with one embodiment.

FIG. 5 illustrates a two dimensional representation of an example of rounded structures for a template layer shown in FIG. 1 in accordance with one embodiment.

FIG. 6 is a cross-sectional view of a PV cell that includes a plurality of template layers in accordance with another embodiment.

FIG. 7 is a cross-sectional view of a PV cell having a textured electrode in accordance with another embodiment.

FIG. 8 is a cross-sectional view of a PV cell having a textured template layer formed of discrete layers in accordance with another embodiment.

FIG. 9 is a cross-sectional view of a PV cell having a textured substrate in accordance with another embodiment.

FIG. 10 is a flowchart of a method for providing a PV device with a textured template layer in accordance with one embodiment.

FIG. 11 is a flowchart of a method for providing a PV device with multiple textured template layers in accordance with one embodiment.

FIG. 12 is a flowchart of a method for providing a PV device with a textured electrode in accordance with one embodiment.

FIG. 13 is a flowchart of a method for providing a PV device with a textured template layer formed of discrete layers in accordance with one embodiment.

FIG. 14 is a flowchart of a method for providing a PV device with a textured substrate in accordance with one embodiment.

The foregoing summary, as well as the following detailed description of certain embodiments of the presently described technology, will be better understood when read in conjunction with the appended drawings. For the purpose of illustrating the presently described technology, certain embodiments are shown in the drawings. It should be understood, however, that the presently described technology is not limited to the arrangements and instrumentality shown in the attached drawings. Moreover, it should be understood that the components in the drawings are not to scale and the relative sizes of one component to another should not be construed or interpreted to require such relative sizes.

### DETAILED DESCRIPTION OF THE INVENTION

The foregoing summary, as well as the following detailed description of certain embodiments of the subject matter set forth herein, will be better understood when read in conjunction with the appended drawings. As used herein, an element or step recited in the singular and proceeded with the word “a” or “an” should be understood as not excluding plural of said elements or steps, unless such exclusion is explicitly stated. Furthermore, references to “one embodiment” are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

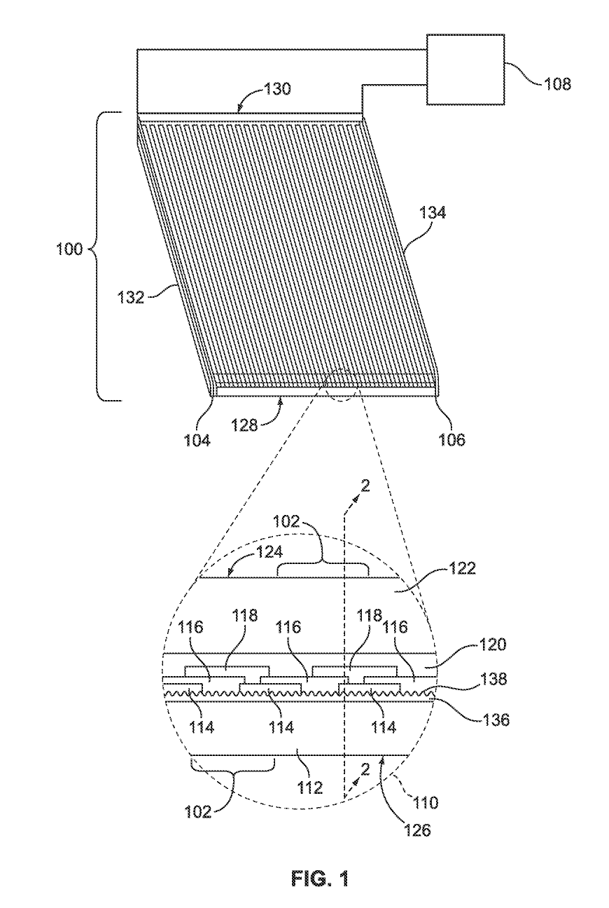

FIG. 1 is a perspective view of a schematic diagram of a photovoltaic (PV) device 100 and a detail view 110 of a cross-sectional portion of the PV device 100 according to one embodiment. The PV device 100 includes a plurality of PV cells 102 electrically connected with each other. For example, the PV device 100 may have one hundred or more PV cells 102 connected with one another in series. The outermost PV cells 102 that are located at or near opposite sides 132, 134 of the PV device 100 are electrically coupled with respective conductive leads 104, 106. The leads 104, 106 may extend between opposite ends 128, 130 of the PV device 100. The leads 104, 106 are connected with a circuit 108 that includes an electrical load to which the current generated by the PV device 100 is collected or applied. For example, the current generated by the PV device 100 may be collected at an energy storage device, such as a battery, and/or may be applied to a device that consumes at least some of the current to perform a function.

The PV cells 102 include stacks of multiple layers. In one embodiment, the PV cells 102 include a supporting substrate 112, a textured template layer 136, bottom electrodes 114, semiconductor layer stacks 116, top electrodes 118, a top adhesive layer 120 and a cover sheet 122. The top electrode 118 of one PV cell 102 may be electrically connected with the bottom electrode 114 in a neighboring PV cell 102 in order to electrically couple the PV cells 102 in series.

The PV device 100 generates electric current from light that is incident on a top surface 124 of the cover sheet 122. The light passes through the cover sheet 122, the top adhesive 120, and the top electrodes 118. At least some of the light is absorbed by the semiconductor layer stacks 116 as the light initially enters into and passes through the semiconductor layer stacks 116. The semiconductor layer stack 116 may include an N-I-P or P-I-N stack of doped semiconductor layers or films 126, 128, 130 in the illustrated embodiment. Alternatively, the semiconductor layer stack 116 may include multiple N-I-P and/or P-I-N stacks of doped semiconductor layers or films 126, 128, 130. Some of the light may pass through the semiconductor layer stacks 116. The light that passes through the semiconductor layer stacks 116 may be reflected back into the semiconductor layer stack 116 by the template layer 136 and/or the bottom electrodes 114.

As the light initially passes through the semiconductor layer stacks 116 and/or as the light is reflected back into the semiconductor layer stacks 116 from the template layer 136, photons in the light excite electrons in the semiconductor layer stack 116. Depending on the wavelength of the light and the energy band gap of the materials in the semiconductor layer stack 116, the photons of the light may excite the electrons and cause the electrons to separate from atoms in the semiconductor layer stack 116. Complementary positive charges, or holes, are created when the electrons separate from the atoms. The semiconductor layers or films 126, 128, 130 in the semiconductor layer stack 116 that produce electron-hole pairs when the light passes through the films 126, 128, 130 may be referred to as active layers or films. The electrons drift or diffuse through the semiconductor layer stack 116 and are collected at the top or bottom electrodes 118, 114. The holes drift or diffuse through the semiconductor layer stacks 116 and are collected at the other of the top and bottom electrodes 118, 114. The collection of the electrons and holes at the top and bottom electrodes 118, 114 generates a voltage difference in the PV cell 102. The voltage difference in the PV cells 102 may be additive across the entire PV device 100. For example, the voltage difference in each of the PV cells 102 may be added together. As the number of PV cells 102 increases, the additive voltage difference across the series of PV cells 102 also may increase.

The electrons and holes flow through the top and bottom electrodes 118, 114 in one PV cell 102 to the opposite electrodes 114, 118 in a neighboring PV cell 102. For example, if the electrons flow to the bottom electrode 114 in a first PV cell 102 when light strikes the semiconductor layer stack 116, then the electrons flow through the bottom electrode 114 to the top electrode 118 in the neighboring PV cell 102. Similarly, if the holes flow to the top electrode 118 in the first PV cell 102, then the holes flow through the top electrode 118 to the bottom electrode 114 in the neighboring PV cell 102.

Electric current and voltage is generated by the flow of electrons and holes through the top and bottom electrodes 118, 114 and between neighboring PV cells 102. The voltage generated by each PV cell 102 is added in series across the plurality of PV cells 102. The current is then drawn to the circuit 108 through the connection of the leads 104, 106 to the top and bottom electrodes 118, 114 in the outermost PV cells 102. For example, a first lead 104 may be electrically connected to the top electrode 118 in the left-most PV cell 102 while a second lead 106 is electrically connected to the bottom electrode 114 in the right-most PV cell 102.

In accordance with one embodiment, the template layer 136 has a predetermined textured shape that causes one or more reflective surfaces between the semiconductor layer stack 116 and the substrate 112 to have a shape that is based on or corresponds to the template layer 136. The template layer 136 has a controlled or predetermined undulating upper surface 138. As described below, the upper surface 138 may be defined by a regular or periodic array of predetermined structures 300, 400, 500 (shown in FIGS. 3 through 5), such as three-dimensional cones, pyramids, cylinders, and the like. The reflective surfaces that reflect the light may be part of the bottom electrode 114 as some other layer of the PV cell 102. The textured shape of the reflective surfaces may cause incident light to scatter and be reflected back into the semiconductor layer stack in a variety of different directions. The scattering of the light back into the semiconductor layer stack 116 may excite additional electrons from atoms in order to increase the voltage differential generated in the PV cells 102.

The upper surface 138 of the template layer 136 may impart a controlled or predetermined shape onto the layers deposited above the template layer 136. For example, the predetermined pattern or array of the template layer 136 may be repeated in one or more layers deposited onto the template layer 136. For example, one or more of the bottom electrodes 114, the semiconductor layer stacks 116, and/or the top electrodes 118 may have a shape that corresponds to, matches, or conforms to the shape of the template layer 136. The template layer 136 can have a shape that enhances light scattering, light concentration, and absorption of the light in the semiconductor layer stacks 116.

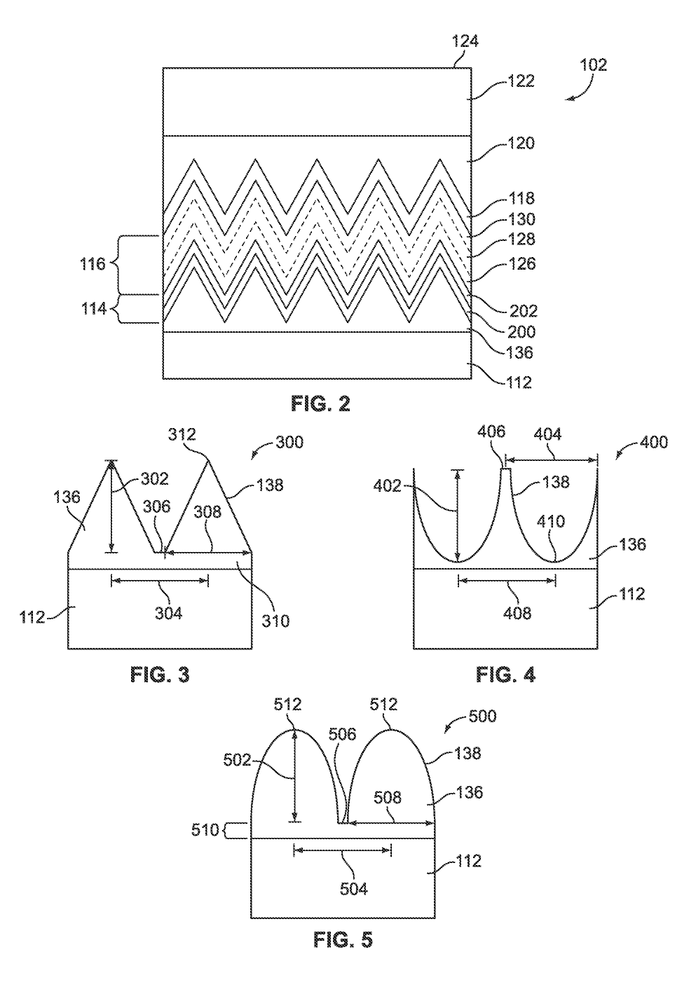

FIG. 2 is a cross-sectional view of the PV cell 102 shown in FIG. 1 along line 2-2 in FIG. 1 in accordance with one embodiment. As described above, the PV cell 102 is a substrate-configuration solar cell in that the PV cell 102 receives light from the side 124 of the PV cell 102 that is opposite of the substrate 112. The substrate 112 is a deposition surface on which the other films or layers of the PV cell 102 are deposited. The substrate 112 may include or be formed from an insulating or conductive material. In one embodiment, the substrate 112 is formed from a glass such as float glass or borosilicate glass. In another embodiment, the substrate 112 may be formed from soda-lime float glass, low iron float glass or a glass that includes at least 10 percent by weight of sodium oxide (Na₂O). In another embodiment, the substrate 112 is formed from a ceramic such as silicon nitride (Si₃N₄) or aluminum oxide (alumina, or Al₂O₃). In another embodiment, the substrate 112 is formed from a conductive material such as a metal or metal alloy. For example, the substrate 112 may be formed from stainless steel, aluminum, titanium, polyenthylenterephtalate (PET), polyethylennaphtalate (PEN), and the like.

The template layer 136 is deposited onto the substrate 112. The template layer 136 may include or be formed from an insulating or conductive material that is able to withstand the temperatures experienced by the template layer 136 during deposition of the bottom electrode 114, the semiconductor layer stack 116, and/or the top electrode 118. For example, the template layer 136 may be formed of a material that can withstand temperatures of at least 200 degrees Celsius. In another embodiment, the template layer 136 may need to withstand temperatures of at least 400 degrees Celsius.

The template layer 136 can be formed from amorphous silicon that is deposited onto the substrate 112 and then etched for form structures, such as the structures 300, 400, 500 (shown in FIGS. 3 through 5) that reflect incident light. The template layer 136 may be etched using reactive ion etching of the template layer 136. An etch mask may be placed onto the template layer 136 to prevent areas of the template layer 136 from being etched and to form the structures 300, 400, 500 in the template layer 136. By way of example only, silicon dioxide bodies, such as spheres, may be deposited onto the template layer 136 before depositing the bottom electrode 114. The template layer 136 may then be etched with the silicon dioxide bodies preventing the areas of the template layer 136 that are covered by the bodies from being removed.

In another example, the template layer 136 may be formed by depositing a metal or metal alloy layer onto the substrate 112, such as by sputtering, and then anodizing the metal or metal alloy layer. In one embodiment, the template layer 136 is deposited by sputtering aluminum and tantalum onto the substrate 112 and then anodizing the aluminum and tantalum to form the structures 300, 400, 500 (shown in FIGS. 3 through 5) in the template layer 136. The template layer 136 may be anodized by placing the substrate 112 and template layer 136 into a liquid bath that includes an acid. A voltage differential is applied between the template layer 136 and a conductive member that is also placed into the bath. A positive voltage is applied to the template layer 136 and a negative voltage is applied to the conductive member. The voltage differential releases hydrogen at the conductive member, or cathode, and releases oxygen at the template layer 136, or anode. Aluminum oxide may be formed on the template layer 136. The acid in the liquid bath may dissolve at least some of the aluminum oxide to form the structures 300, 400, 500. An additional immersing of the template layer 136 in an acid bath may further etch the aluminum oxide of the template layer 136 and may define the structures 300, 400, 500. One or more parameters involved in the anodizing of the template layer 136 may be varied to control the shape and/or size of the structures 300, 400, 500. For example, the time that the template layer 136 is immersed in the liquid bath with the voltage differential applied, the type of acid in the liquid bath, the strength of the voltage differential, and/or the time period over which the post-anodizing acid etch occurs may vary the size and/or shape of one or more of the structures 300, 400, 500 described below.

In another embodiment, the template layer 136 is deposited by applying an electrostatic charge to the substrate 112 and then placing the substrate 112 in an atmosphere that includes oppositely charged particles. The charge that is applied to the substrate 112 draws the particles to the substrate 112 and may deposit the particles thereon to form the structures 300, 400, 500 (shown in FIGS. 3 through 5) of the template layer 136. The particles forming the template layer 136 may be held in place by applying an adhesive layer above the template layer 136. Alternatively, the particles may be held in place by annealing the substrate 112 and particles. Examples of particles that may be deposited using electrostatic charges include, but are not limited to, faceted ceramics and diamond-shaped materials. For example, the particles may include or be formed from silicon carbide, alumina (Al₂O₃), aluminum nitride (AlN), diamond, and chemical vapor deposited (CVD) diamond.

The template layer 136 may be separate from the layers of the PV cell 102 that create the voltage differential in the PV cells 102 and/or that convey electric current generated by the PV cells 102. For example, the template layer 136 may not be a conductive layer that transmits voltage or current to or from either of the electrodes 114, 118 and the template layer 136 may not be a layer that generates electrons and/or holes when incident light strikes the template layer 136. Alternatively, template layer 136 may form part of the bottom electrodes 114. For example, the template layer 136 may include a reflective conductive material that is electrically coupled with the bottom electrodes 114 deposited onto the template layer 136.

In embodiments where the template layer 136 is an insulating or dielectric material that does not conduct electric current between adjacent cells 102 in a PV device 100 (shown in FIG. 1), the template layer 136 may continuously extend between adjacent cells 102, as is shown in FIG. 1. Alternatively, if the template layer 136 conducts electric current, then portions or the template layer 136 that are located between adjacent cells 102 may be removed to electrically isolate the bottom electrodes 114 of the adjacent cells 102. For example, if the template layer 136 includes or is formed from a metal or metal alloy, then the template layer 136 may be etched between the cells 102 to ensure that electric current does not pass from the bottom electrode 114 of one cell 102 and through the template layer 136 to the bottom electrode 114 of an adjacent cell 102.

In embodiments where the substrate 112 is a conducting material, the template layer 136 may be deposited onto the substrate 112 as an insulating or dielectric material that continuously extends between adjacent cells 102. For example, where the substrate 112 includes a metal or metal alloy, the template layer 136 may not be etched or removed between the cells 102. Alternatively, if the substrate 112 and the template layer 136 both are conducting materials, then an additional insulating layer may be placed between the conductive substrate 112 and the conductive template layer 136. For example, if both the substrate 112 and the template layer 136 include metals or metal alloys, then an insulating layer of material may be deposited on the substrate 112 before the template layer 136 is deposited. The additional insulating layer electrically separates the template layer 136 from the substrate 112 such that there is no conductive pathway that directly couples current being transmitted in the template layer 136 into the substrate 112. The template layer 136 may be removed between the cells 102 similar to as described above to avoid the template layer 136 establishing a conductive pathway that extends between the bottom electrodes 114 in adjacent cells 102.

The template layer 136 is at least partially opaque in one embodiment. For example, the template layer 136 may not permit light to pass through the template layer 136 as the light. The template layer 136 may be light reflective. For example, the template layer 136 may be formed of a reflective material or may include an upper film or layer of reflective material that reflects incident light. For example, the template layer 136 may have a reflective silver (Ag) layer or film on the upper surface 138 at the interface between the template layer 136 and the bottom electrode 114. Such a conductive and reflective layer or film may be electrically coupled with the bottom electrode 114.

In another embodiment, the template layer 136 is a non-reflective layer. The non-reflective template layer 136 may be deposited to impart a controlled or predetermined shape onto the bottom electrode 114. For example, the bottom electrodes 114 may be reflective to light. The bottom electrodes 114 are deposited onto the template layer 136 so that the reflective bottom electrodes 114 have the same or approximately the same shape as the template layer 136. The shaped bottom electrodes 114 may then reflect and scatter the incident light similar to the template layer 136 if the template layer 136 was reflective to light. In one embodiment, the bottom electrode 114 includes a conductive reflector layer 200 deposited onto the template layer 136 and a transparent conductive layer 202 deposited onto the reflector layer 200. For example, the reflector layer 200 may be a conductive layer or film that carries electric current and may reflect incident light back into the semiconductor layer stack 116. By way of example only, the reflector layer 200 may include or be formed from silver, aluminum, a silver alloy, or an aluminum alloy. The reflector layer 200 may be deposited in a variety of thicknesses. For example, the reflector layer 200 may be deposited at a thickness of approximately 100 to 300 nanometers.

The conductive layer 202 provides an electrical contact to the semiconductor layer stack 116. For example, the electrons or holes that are generated in the semiconductor layer stack 116 may be transmitted into the conductive layer 202. The conductive layer 202 is referred to as a “transparent” conductive layer in that the conductive layer 202 includes or is formed from a conductive material and permits at least some light to pass through the conductive layer 202. Use of the term “transparent” is not intended to limit the conductive layer 202 to materials that are completely transparent to light. By way of example only, the conductive layer 202 may include or be formed from one or more of aluminum doped zinc oxide, zinc oxide, and indium tin oxide.

The conductive layer 202 may act as a buffer layer that provides a chemical and/or optical buffer between the semiconductor layer stack 116 and the reflector layer 200. For example, the conductive layer 202 may provide a chemical buffer that impedes or prevents diffusion of dopants and/or impurities between the reflector layer 200 and the semiconductor layer stack 116.

The conductive layer 202 may provide an optical buffer that has a thickness dimension tuned to one or more wavelengths of light. For example, the thickness dimension of the conductive layer 202 that extends between the reflector layer 200 and the semiconductor layer stack 116 may be varied based on the wavelengths of light that are to be reflected back into the semiconductor layer stack 116. The energy of photons in the reflected light is based on the wavelength of the light. Therefore, in order to control the energy of at least some of the photons in the light that is reflected into the semiconductor layer stack 116, the thickness of the conductor layer 202 may be established to allow a greater amount of light of a predetermined wavelength to be reflected back into the semiconductor layer stack 116 relative to other wavelengths of the light. By tailoring the thickness of the conductor layer 202 to amplify the amount of reflected light having predetermined wavelength, the amount of electron/hole pairs generated in the semiconductor layer stack 116 can be increased. By way of example only, the typical thickness range for the conductive layer 202 may be between 50 and 500 nanometers.

The semiconductor layer stack 116 may include one or more layers or films of semiconductor materials, such as silicon. Alternatively, the semiconductor layer stack 116 may include or be formed from cadmium telluride, cadmium, Indium, gallium, selenium and the like. The semiconductor layer stacks 116 may include a P-I-N or N-I-P type junction or a tandem structure with two or more P-I-N or N-I-P junctions. For example, the semiconductor layer stacks 116 may include films of p-doped silicon, intrinsic silicon, and n-doped silicon deposited on each other. The semiconductor materials in the semiconductor layer stacks 116 may be amorphous or microcrystalline, or a combination thereof.

The top electrode 118 is deposited onto the semiconductor layer stack 116. The top electrode 118 includes or is formed from a “transparent” conductive material to permit light to pass through the top electrode 118 while also conducting electric current within the PV device 100 (shown in FIG. 1). Use of the term “transparent” is not intended to limit the top electrode 118 to materials that are completely transparent to light. By way of example only, the top electrode 118 may include or be formed from one or more of aluminum doped zinc oxide, zinc oxide, and indium tin oxide.

As shown in FIG. 2, the template layer 136 may impart a shape onto the layers deposited onto the template layer 136. For example, the peaks and valleys of the template layer 136 may be repeated in the bottom electrode 114, the semiconductor layer stack 116, and/or the top electrode 118. The top electrode 118 may have a textured pattern that corresponds to and is based on the template layer 136. The textured top electrode 118 may create an anti-reflection property and capture more incident light. For example, the textured top electrode 118 may cause more light to pass through the top electrode 118 and into the semiconductor layer stack 116 than is reflected by the top electrode 118 away from the semiconductor layer stack 116. Incident light that passes through the top electrode 118, semiconductor layer stack 116, and bottom electrode 114 and is perpendicular to the substrate 112 or near perpendicular to the substrate 112 may reflect off of different structures 300, 400, 500 (shown in FIGS. 3 through 5) of the template layer 136 and back into the semiconductor layer stack 116. Similarly, light that is incident on the top electrode 118 at an acute or a glancing angle may be more likely to strike one or more structures 300, 400, 500 present in the top electrode 118. The structures 300, 400, 500 may prevent the glancing light from being reflected away from the semiconductor layer stack 116. Instead, the glancing light may strike the structures 300, 400, 500 and pass through the top electrode 118 into the semiconductor layer stack 116.

The adhesive layer 120 and cover sheet 122 are placed onto the top electrode 118. The shape of the template layer 136 may be determined or controlled by one or more parameters of the template layer 136. The parameters are controlled to increase the amount of light that is trapped in the active layers of the PV cell 102 (shown in FIG. 1). For example, the parameters of the template layer 136 may be varied to increase the amount of light that passes through the semiconductor layer stacks 116 (shown in FIG. 1) and is reflected off of the reflector layer 200 (shown in FIG. 2) and/or the template layer 136 back into the semiconductor layer stack 116.

Parameters of the template layer 136 may be varied to increase the amount of light trapping for a desired or predetermined range of wavelengths of incident light. For example, a template layer 136 can be deposited with structures 300, 400, 500 (shown in FIGS. 3 through 5) that include three dimensional cones, paraboloids, and/or pyramids having a controlled pitch, height, and/or shape that are based on a crystalline structure of one or more layers or films 126, 128, 130 in the semiconductor layer stack 116. The parameters may be adapted to increase light scattering and absorption in the visible range of wavelengths of light for amorphous silicon layers of the semiconductor layer stack 116, or in the infrared range of wavelengths of light for microcrystalline silicon layers of the semiconductor layer stack 116.

Multiple light scattering structures 300, 400, 500 (shown in FIGS. 3 through 5) and patterns of structures 300, 400, 500 may be implemented in a PV cell 102 to enhance light scattering and collection of the light in multiple active layers within the PV cell 102. For example, one pattern of structures 300, 400, 500 in the template layer 136 may be used adjacent to an amorphous active layer of the semiconductor layer stack 116 to enhance light scattering in the visible layer and a second pattern of structures 300, 400, 500 in the template layer 136 may be used adjacent to a microcrystalline active layer of the semiconductor layer stack 116 to enhance light scattering in the infrared layer.

FIGS. 3 through 5 illustrate two dimensional representations of examples of different structures 300, 400, 500 that establish the predetermined shapes of the template layer 136 in accordance with several embodiments. The structures 300, 400, 500 are created in the template layer 136 to impart a predetermined texture in the upper surface 138 of the template layer 136 and/or in the layers deposited or provided above the template layer 136. For example, the structures 300, 400, 500 may be generated during deposition or etching of the template layer 136 to impart a desired texture or pattern in the bottom electrode 114. The template layer 136 may include a single type of structure 300, 400, 500 repeated throughout the template layer 136 or may include a combination of two or more of the structures 300, 400, and/or 500.

The structures 300 shown in FIG. 3 are referred to as peak structures 300 as the structures 300 appear as sharp peaks along the upper surface 138 of the template layer 136. The peak structures 300 are defined by one or more parameters, including a peak height (Hpk) 302, a pitch 304, a transitional shape 306, and a base width (Wb) 308. As shown in FIG. 3, the peak structures 300 are formed as shapes that decrease in width as the distance from the substrate 112 increases. For example, the peak structures 300 decrease in size from bases 310 located at or near the substrate 112 to several peaks 312. The structures 300 are represented as triangles in the two dimensional view of FIG. 3, but alternatively may have a pyramidal or conical shape in three dimensions.

The peak height (Hpk) 302 represents the average or median distance of the peaks 312 from the transitional shapes 306 between the structures 300. For example, the template layer 136 may be deposited as an approximately flat layer up to the bases 310 of the peaks 312, or to the area of the transitional shape 306. The template layer 136 may continue to be deposited in order to form the peaks 312. The distance between the bases 310 or transitional shape 306 to the peaks 312 may be the peak height (Hpk) 302.

The pitch 304 represents the average or median distance between the peaks 312 of the peak structures 300. The pitch 304 may be approximately the same in two or more directions. For example, the pitch 304 may be the same in two perpendicular directions that extend parallel to the substrate 112. In another embodiment, the pitch 304 may differ along different directions. Alternatively, the pitch 304 may represent the average or median distance between other similar points on adjacent structures 300. The transitional shape 306 is the general shape of the upper surface 138 of the template layer 136 between the structures 300. As shown in the illustrated embodiment, the transitional shape 306 can take the form of a flat “facet.” Alternatively, the flat facet shape may be a cone or pyramid when viewed in three dimensions. The base width (Wb) 308 is the average or median distance across the structures 300 at an interface between the structures 300 and the base 310 of the template layer 136. The base width (Wb) 308 may be approximately the same in two or more directions. For example, the base width (Wb) 308 may be the same in two perpendicular directions that extend parallel to the substrate 112. Alternatively, the base width (Wb) 308 may differ along different directions.

FIG. 4 illustrates valley structures 400 of the template layer 136 in accordance with one embodiment. The shapes of the valley structures 400 differ from the shapes of the peak structures 300 shown in FIG. 3 but may be defined by the one or more of the parameters described above in connection with FIG. 3. For example, the valley structures 400 may be defined by a peak height (Hpk) 402, a pitch 404, a transitional shape 406, and a base width (Wb) 408. The valley structures 400 are formed as recesses or cavities that extend into the template layer 136 from the upper surface 138. The valley structures 400 are shown as having a parabolic shape in the two dimensional view of FIG. 4, but may have conical, pyramidal, or paraboloid shapes in three dimensions. In operation, the valley structures 400 may vary slightly from the shape of an ideal parabola.

In general, the valley structures 400 include cavities that extend down into the template layer 136 from the upper surface 138 and toward the substrate 112. The valley structures 400 extend down to low points 410, or nadirs, of the template layer 136 that are located between the transition shapes 406. The peak height (Hpk) 402 represents the average or median distance between the upper surface 412 and the low points 410. The pitch 404 represents the average or median distance between the same or common points of the valley structures 400. For example, the pitch 404 may be the distance between the midpoints of the transition shapes 406 that extend between the valley structures 400. The pitch 404 may be approximately the same in two or more directions. For example, the pitch 404 may be the same in two perpendicular directions that extend parallel to the substrate 112. In another embodiment, the pitch 404 may differ along different directions. Alternatively, the pitch 404 may represent the distance between the low points 410 of the valley structures 400. Alternatively, the pitch 404 may represent the average or median distance between other similar points on adjacent valley structures 400.

The transitional shape 406 is the general shape of the upper surface 138 between the valley structures 400. As shown in the illustrated embodiment, the transitional shape 406 can take the form of a flat “facet.” Alternatively, the flat facet shape may be a cone or pyramid when viewed in three dimensions. The base width (Wb) 408 represents the average or median distance between the low points 410 of adjacent valley structures 400. Alternatively, the base width (Wb) 408 may represent the distance between the midpoints of the transition shapes 406. The base width (Wb) 408 may be approximately the same in two or more directions. For example, the base width (Wb) 408 may be the same in two perpendicular directions that extend parallel to the substrate 112. Alternatively, the base width (Wb) 408 may differ along different directions.

FIG. 5 illustrates rounded structures 500 of the template layer 136 in accordance with one embodiment. The shapes of the rounded structures 500 differ from the shapes of the peak structures 300 shown in FIG. 3 and the valley structures 400 shown in FIG. 4, but may be defined by the one or more of the parameters described above in connection with FIGS. 3 and 4. For example, the rounded structures 500 may be defined by a peak height (Hpk) 502, a pitch 504, a transitional shape 506, and a base width (Wb) 508. The rounded structures 500 are formed as protrusions of the upper surface 138 of the template layer 136 that extend upward from a base film 510 of the template layer 136. The rounded structures 500 may have an approximately parabolic or rounded shape. In operation, the rounded structures 500 may vary slightly from the shape of an ideal parabola. While the rounded structures 500 are represented as parabolas in the two dimensional view of FIG. 5, alternatively the rounded structures 500 may have the shape of a three dimensional paraboloid, pyramid, or cone that extends upward away from the substrate 112.

In general, the rounded structures 500 project upward from the base film 510 and away from the substrate 112 to rounded high points 512, or rounded apexes. The peak height (Hpk) 502 represents the average or median distance between the base film 510 and the high points 512. The pitch 504 represents the average or median distance between the same or common points of the rounded structures 500. For example, the pitch 504 may be the distance between the high points 512. The pitch 504 may be approximately the same in two or more directions. For example, the pitch 504 may be the same in two perpendicular directions that extend parallel to the substrate 112. Alternatively, the pitch 504 may differ along different directions. In another example, the pitch 504 may represent the distance between midpoints of the transition shapes 506 that extend between the rounded structures 500. Alternatively, the pitch 504 may represent the average or median distance between other similar points on adjacent rounded structures 500.

The transitional shape 506 is the general shape of the upper surface 138 between the rounded structures 500. As shown in the illustrated embodiment, the transitional shape 506 can take the form of a flat “facet.” Alternatively, the flat facet shape may be a cone or pyramid when viewed in three dimensions. The base width (Wb) 508 represents the average or median distance between the transition shapes 506 on opposite sides of a rounded structure 500. Alternatively, the base width (Wb) 508 may represent the distance between the midpoints of the transition shapes 506.

In accordance with one embodiment, the pitch 304, 404, 504 and/or base width (Wb) 308, 408, 508 of the structures 300, 400, 500 are approximately 400 nanometers to approximately 1500 nanometers. Alternatively, the pitch 304, 404, 504 of the structures 300, 400, 500 may be smaller than approximately 400 nanometers or larger than approximately 1500 nanometers. The average or median peak height (Hpk) 302, 402, 502 of the structures 300, 400, 500 may be approximately 25 to 80% of the pitch 304, 404, 504 for the corresponding structure 300, 400, 500. Alternatively, the average peak height (Hpk) 302, 402, 502 may be a different fraction of the pitch 304, 404, 504. The base width (Wb) 308, 408, 508 may be approximately the same as the pitch 304, 404, 504. Alternatively, the base witdh (Wb) 308, 408, 508 may differ from the pitch 304, 404, 504. The base width (Wb) 308, 408, 508 may be approximately the same in two or more directions. For example, the base width (Wb) 308, 408, 508 may be the same in two perpendicular directions that extend parallel to the substrate 112. Alternatively, the base width (Wb) 308, 408, 508 may differ along different directions.

The parameters of the structures 300, 400, 500 in a template layer 136 may vary based on whether the PV cell 102 (shown in FIG. 1) is a dual- or triple-junction cell 102 and/or on which of the semiconductor films or layer in the semiconductor layer stack 116 is the current-limiting layer. For example, the semiconductor layer stack 116 may include a single N-I-P or a single P-I-N stack of doped amorphous or doped microcrystalline semiconductor layers, or two or more stacks of N-I-P and/or P-I-N doped amorphous or doped microcrystalline silicon layers. One or more parameters described above may be based on which of the semiconductor layers in the N-I-P and/or P-I-N stacks is the current-limiting layer. For example, one or more of the layers in the N-I-P and/or P-I-N stacks may limit the amount of current that is generated by the PV cell 102 when light strikes the PV cell 102. One or more of the parameters of the structures 300, 400, 500 may be based on which of these layers is the current-limiting layer.

In one embodiment, if the PV cell 102 (shown in FIG. 1) includes a microcrystalline silicon layer in the semiconductor layer stack 116 (shown in FIG. 1) and the microcrystalline silicon layer is the current limiting layer of the semiconductor layer stack 116, the pitch 304, 404, 504 of the structures 300, 400, 500 in the template layer 136 below the microcrystalline silicon layer may be between approximately 500 and 1500 nanometers. The microcrystalline silicon layer has an energy bandgap that corresponds to infrared light having wavelengths between approximately 500 and 1500 nanometers. For example, the structures 300, 400, 500 may reflect an increased amount of infrared light having wavelengths of between 500 and 1500 nanometers if the pitch 304, 404, 504 is approximately matched to the wavelengths. The transitional shape 306, 406, 506 of the structures 300, 400, 500 may be a flat facet and the base width (Wb) 308, 408, 508 may be 60% to 100% of the pitch 304, 404, 504. The peak height (Hpk) 302, 402, 502 may be between 25% to 75% of the pitch 304, 404, 504. For example, a ratio of the peak height (Hpk) 302, 402, 502 to the pitch 304, 404, 504 may provide scattering angles in the structures 300, 400, 500 that reflect more light back into the semiconductor layer stack 116 relative to other ratios.

In another example, if the PV cell 102 includes a tandem of two semiconductor layer stacks 116 stacked one above the other, with one layer stack 116 being amorphous semiconductor layers and the other layer stack 116 being microcrystalline semiconductor layers, the range of pitches 304, 404, 504 for the template layer 136 may vary based on which of the layer stacks 116 is the current limiting stack. If the PV cell 102 is a dual junction microcrystalline silicon/amorphous silicon tandem cell that includes a microcrystalline N-I-P or P-I-N doped semiconductor layer stack 116 deposited above an amorphous N-I-P or P-I-N doped semiconductor layer stack 116 and the microcrystalline semiconductor layer stack 116 is the current limiting layer, then the pitch 304, 504, 604 may be between approximately 500 and 1500 nanometers. In contrast, if the amorphous semiconductor layer stack 116 is the current limiting layer, then the pitch 304, 404, 504 may be between approximately 350 and 1000 nanometers.

With respect to PV cells 102 (shown in FIG. 1) that include a single semiconductor layer stack 116 of N-I-P or P-I-N doped semiconductor films, one or more of the parameters of the structures 300, 400, 500 may vary based on the crystalline nature or structure of the semiconductor layer stack 116 (shown in FIG. 1). For example, in a PV cell 102 that includes a single N-I-P or P-I-N stack of amorphous silicon layers in the semiconductor layer stack 116, the template layer 136 may have structures 300, 400, 500 with pitches 304, 404, 504 of approximately 500 nanometers. The transitional shapes 306, 406, 506 of the structures 300, 400, 500 may be a flat surface and the base width (Wb) 308, 408, 508 may be approximately 500 nanometers. The height (Hpk) 302, 402, 502 may be approximately 250 nanometers. In another example, in a PV cell 102 that includes a single N-I-P or P-I-N stack of microcrystalline silicon layers in the semiconductor layer stack 116, the template layer 136 may have structures 300, 400, 500 with larger pitches 304, 404, 504 of approximately 1000 nanometers. The transitional shapes 306, 406, 506 of the structures 300, 400, 500 may be a flat surface and the base width (Wb) 308, 408, 508 may be larger, such as approximately 1000 nanometers. The height (Hpk) 302, 402, 502 may be approximately 500 nanometers.

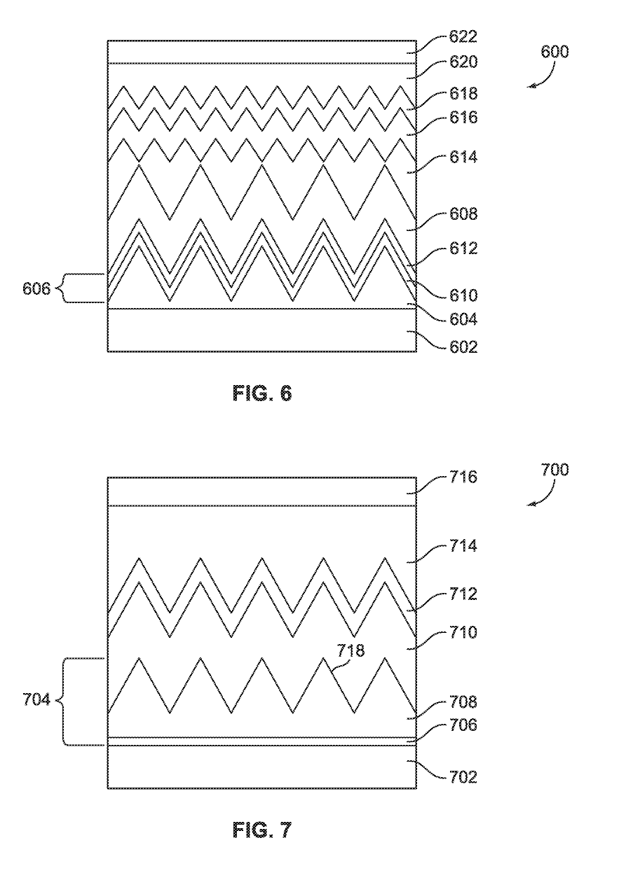

FIG. 6 is a cross-sectional view of a PV cell 600 that includes a plurality of template layers 604, 614 in accordance with another embodiment. The PV cell 600 may be similar to the PV cell 102 (shown in FIG. 1) in that several PV cells 600 may be electrically connected to form the PV device 100 (shown in FIG. 1). The PV cell 600 includes a substrate 602 that may be similar to the substrate 112 (shown in FIG. 1), a lower template layer 604 that may be similar to the template layer 136 (shown in FIG. 1), a bottom electrode 606 that may be similar to the bottom electrode 114 (shown in FIG. 1), and a lower semiconductor layer stack 608 that may be similar to the semiconductor layer stack 116 (shown in FIG. 1). The bottom electrode 606 may include a reflector layer 610 and a conductive layer 612 that are similar to the reflector layer 200 and the conductive layer 202 (shown in FIG. 2) of the bottom electrode 114.

The PV cell 600 includes an upper template layer 614 that is deposited on or above the lower semiconductor layer stack 608. The upper template layer 614 may be deposited using techniques described herein to include one or more structures 300, 400, and/or 500 (shown in FIGS. 3 through 5). The pattern of structures 300, 400, 500 in the template layers 604, 614 may differ from each other, as shown in FIG. 6. For example, the pitch 304, 404, 504 (shown in FIGS. 3 through 5) of the structures 300, 400, 500 may be larger in the lower template layer 604 than in the upper template layer 614.

An upper semiconductor layer stack 616 is deposited onto the upper template layer 614. The upper semiconductor layer stack 616 may be similar to the semiconductor layer stack 116 (shown in FIG. 1) in that the upper semiconductor layer stack 616 may include an N-I-P or P-I-N doped amorphous or microcrystalline semiconductor layer stack. In one embodiment, the lower semiconductor layer stack 608 is an N-I-P or P-I-N stack of microcrystalline semiconductor layers while the upper semiconductor layer stack 616 is an N-I-P or P-I-N stack of amorphous semiconductor layers. The parameters that define the structures 300, 400, 500 (shown in FIGS. 3 through 5) in each of the upper and lower template layers 614, 604 may be matched to the semiconductor layer stacks 616, 608 deposited above the template layers 614, 604. For example, the pitch 304, 404, 504 (shown in FIGS. 3 through 5) of the structures 300, 400, 500 in the upper template layer 614 may be smaller than the pitch 304, 404, 504 of the structures 300, 400, 500 in the lower template layer 604. As described above, the pitch 304, 404, 504 of the structures 300, 400, 500 in each template layer 604, 614 may be based on the wavelengths of light that are to be captured or used to excite electrons in the corresponding semiconductor layer stacks 608, 616.

A top electrode 618 that may be similar to the top electrode 118 (shown in FIG. 1) may be deposited on the upper semiconductor layer stack 616. An adhesive layer 620 that is similar to the adhesive layer 120 (shown in FIG. 1) may be deposited on the top electrode 618. A cover sheet 622 that is similar to the cover sheet 122 (shown in FIG. 1) may be positioned on the adhesive layer 620.

FIG. 7 is a cross-sectional view of a PV cell 700 having a textured electrode 704 in accordance with another embodiment. The PV cell 700 may be similar to the PV cell 102 (shown in FIG. 1) in that several PV cells 700 may be electrically connected to form the PV device 100 (shown in FIG. 1). The PV cell 700 includes a substrate 702 that may be similar to the substrate 112 (shown in FIG. 1). A template layer 704 is deposited on the substrate 702 and may be shaped to include one or more structures 300, 400, 500 (shown in FIGS. 3 through 5) described above. In the illustrated embodiment, the template layer 704 includes a reflective layer 706 deposited on the substrate 702 and a conductive layer 708 that is deposited onto the reflective layer 706. The reflective layer 706 may include or be formed from a metal or metal alloy that reflects incident light. The conductive layer 708 may be formed from a light transmissive and conductive material, such as one or more of the materials that the conductive layers 202 (shown in FIG. 2), 612 (shown in FIG. 6). The reflective layer 706 and the conductive layer 708 may be electrically coupled and may serve as a bottom electrode for the PV cell 700. A semiconductor layer stack 710 that may be similar to the semiconductor layer stack 116 (shown in FIG. 1) is deposited on the template layer 704.

The reflective layer 706 may be deposited as an approximately smooth layer. The conductive layer 708 may be deposited and/or etched to have an undulating upper surface 718. Similar to the upper surface 138 (shown in FIG. 1) of the template layer 136 (shown in FIG. 1), the upper surface 718 of the conductive layer 708 may have a predetermined pattern or array of one or more of the structures 300, 400, and/or 500 (shown in FIGS. 3 through 5) in order to scatter incident light toward the reflector layer 706. Incident light that passes through a semiconductor layer stack 710 deposited on the bottom electrode 704 may reflect at least some of the light back into the semiconductor layer stack 710. Some of the light may pass through the conductive layer 708 and reflect off of the reflective layer 706. Depending on the angle at which the incident light strikes the structures 300, 400, 500 of the conductive layer 708, the light may change paths across the interface between the semiconductor layer stack 710 and the conductive layer 708. For example, incident light may pass through the semiconductor layer stack 710 and reach the conductive layer 708 along a path that is oriented perpendicular to the surface of the substrate 702. Based on the angles at which the light strikes the structures 300, 400, 500 of the conductive layer 708, the light may pass through the conductive layer 708 and strike the reflector layer 706 at an oblique angle. The light is then reflected back through the conductive layer 708 and into the semiconductor layer stack 710 at a different angle than the light initially passed through the semiconductor layer stack 710. Changing the angle at which the reflected light passes back through the semiconductor layer stack 710 may increase the amount of the light that is trapped, or that excites electrons in the semiconductor layer stack 710.

A top electrode 712 that may be similar to the top electrode 118 (shown in FIG. 1) may be deposited on the semiconductor layer stack 710. An adhesive layer 714 that is similar to the adhesive layer 120 (shown in FIG. 1) may be deposited on the top electrode 712. A cover sheet 716 that is similar to the cover sheet 122 (shown in FIG. 1) may be positioned on the adhesive layer 714.

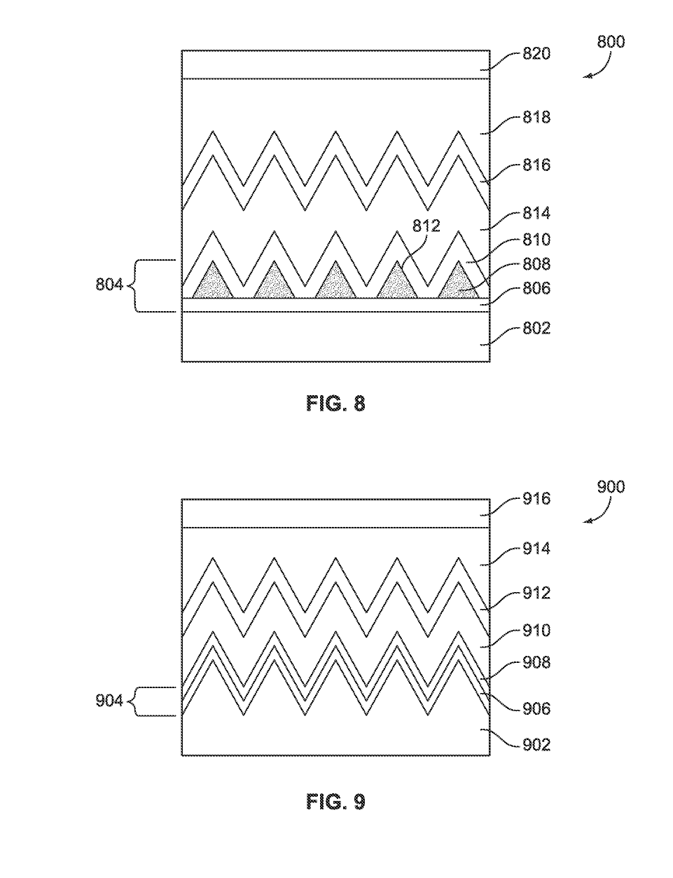

FIG. 8 is a cross-sectional view of a PV cell 800 having a textured template layer 804 formed of discrete layers in accordance with another embodiment. The PV cell 800 may be similar to the PV cell 102 (shown in FIG. 1) in that several PV cells 800 may be electrically connected to form the PV device 100 (shown in FIG. 1). The PV cell 800 includes a substrate 802 that may be similar to the substrate 112 (shown in FIG. 1).

A template layer 804 is deposited on the substrate 802. The template layer 804 includes a reflector layer 806 and a texturing layer 808. The reflector layer 806 may be similar to the reflector layer 706 (shown in FIG. 7). For example, the reflector layer 806 can be a reflective metal or metal alloy deposited on the substrate 802. The texturing layer 808 may be a periodic or array of discrete island bodies 812 deposited on the reflector layer 806. The island bodies 812 of the texturing layer 808 may be discrete and separate from each other, as shown in FIG. 8, or may be connected with each other. The texturing layer 808 may be formed by depositing dielectric and/or conductive particles onto the reflector layer 808. The particles are sized and/or positioned on the reflector layer 806 to form one or more of the structures 300, 400, and/or 500 (shown in FIGS. 3 through 5).

A bottom electrode 810 is deposited onto the texturing layer 808 alone, or on the texturing layer 808 and the reflector layer 806, as shown in FIG. 8. The bottom electrode 810 may be similar to the conductive layer 122 (shown in FIG. 1) of the bottom electrode 114 (shown in FIG. 1). For example, the bottom electrode 810 includes or is formed a light transmissive, conductive material in one embodiment. The bottom electrode 810 may contact and be electrically coupled with the conductive reflector layer 806 between the islands 812 of the texturing layer 808. If the islands 812 are conductive, the bottom electrode 810 may be electrically joined with the islands 812 and the reflector layer 806.

A semiconductor layer stack 814 that is similar to the semiconductor layer stack 116 (shown in FIG. 1) is deposited on the bottom electrode 810. A top electrode 816 that may be similar to the top electrode 118 (shown in FIG. 1) may be deposited on the semiconductor layer stack 814. An adhesive layer 818 that is similar to the adhesive layer 120 (shown in FIG. 1) may be deposited on the top electrode 816. A cover sheet 820 that is similar to the cover sheet 122 (shown in FIG. 1) may be positioned on the adhesive layer 818.

FIG. 9 is a cross-sectional view of a PV cell 900 having a textured substrate 902 in accordance with another embodiment. The PV cell 900 may be similar to the PV cell 102 (shown in FIG. 1) in that several PV cells 900 may be electrically connected to form the PV device 100 (shown in FIG. 1). The PV cell 900 includes a textured substrate 902 that may include or be formed from the same or similar materials as the substrate 112 (shown in FIG. 1). The substrate 902 in the illustrated embodiment includes an integral template layer in that the substrate 902 includes one or more textured shapes that may be similar to the structures 300, 400, and/or 500 (shown in FIGS. 3 through 5). In one embodiment, the substrate 902 is deposited as an approximately flat layer and then etched to form the structures 300, 400, and/or 500. By way of example only, the substrate 902 may be etched by exposing the substrate 902 to an acid bath and/or by bombarding the substrate 902 with particles. In one embodiment, the substrate 902 is grit blasted with a predetermined grit blast material, particle size, particle speed, and/or angle at which the particles strike the substrate 902 based on the desired structures 300, 400, 500.

Once the substrate 902 has the desired texture and structures 300, 400, and/or 500 (shown in FIGS. 3 through 5), a bottom electrode 904 is provided on the substrate 902. The bottom electrode 904 may be similar to the bottom electrode 114 (shown in FIG. 1) and can include a reflector layer 906 and a conductive layer 908 that are similar to the reflector layer 200 and conductive layer 202 (shown in FIG. 2). A semiconductor layer stack 910 that is similar to the semiconductor layer stack 116 (shown in FIG. 1) is provided on the bottom electrode 904. A top electrode 912 that is similar to the top electrode 118 (shown in FIG. 1) is deposited above the semiconductor layer stack 910. An adhesive layer 914 that is similar to the adhesive layer 120 (shown in FIG. 1) may be deposited on the top electrode 912. A cover sheet 916 that is similar to the cover sheet 122 (shown in FIG. 1) may be positioned on the adhesive layer 912.

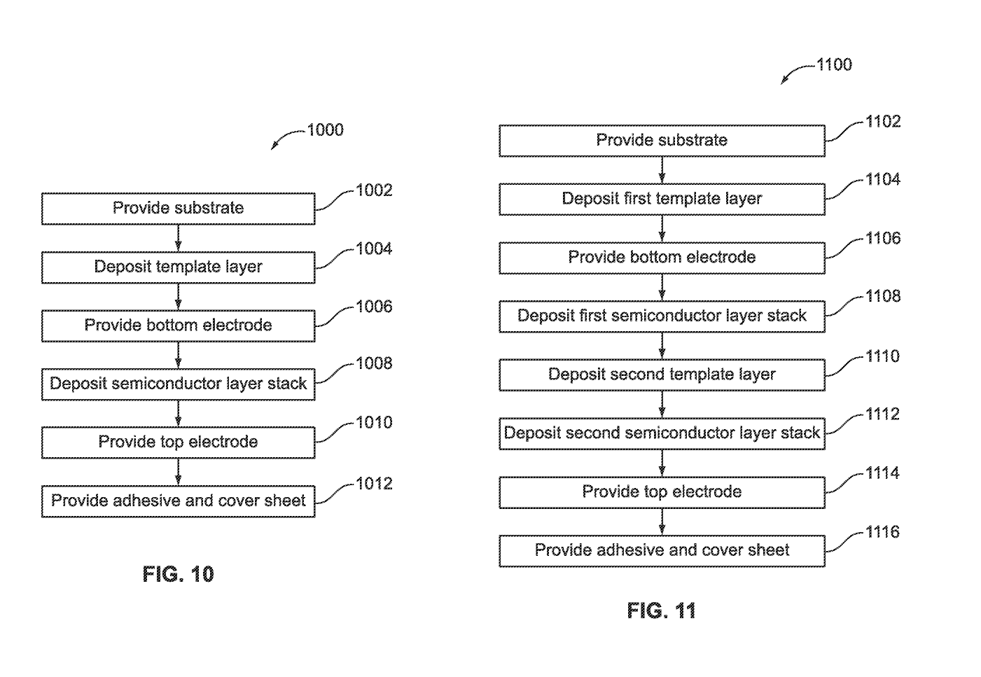

FIG. 10 is a flowchart of a method 1000 for providing a PV device with a textured template layer in accordance with one embodiment. At 1002, a substrate is provided. For example, the substrate 112 (shown in FIG. 1) may be provided. At 1004, a template layer is deposited onto the substrate. For example, the template layer 136 (shown in FIG. 1) may be disposed on the substrate 112. As described above, the template layer imparts a predetermined textured pattern on one or more layers deposited above the template layer in order to scatter and/or reflect light back into a semiconductor layer stack.

At 1006, a bottom electrode is provided above the template layer. For example, the bottom electrode 114 (shown in FIG. 1) may be deposited on the template layer 136 (shown in FIG. 1). At 1008, one or more semiconductor layer stacks, such as the semiconductor layer stack 116 (shown in FIG. 1) is deposited above the bottom electrode 114.

At 1010, a top electrode is provided above the semiconductor layer stack. In one embodiment, the top electrode 118 (shown in FIG. 1) is deposited on the semiconductor layer stack 116 (shown in FIG. 1). At 1012, an adhesive is placed on the top electrode and a cover sheet is provided on the adhesive to enclose the PV device. For example, the adhesive layer 120 (shown in FIG. 1) and cover sheet 122 (shown in FIG. 1) may be provided above the top electrode 118.

FIG. 11 is a flowchart of a method 1100 for providing a PV device with multiple textured template layers in accordance with one embodiment. At 1102, a substrate is provided. For example, the substrate 602 (shown in FIG. 6) may be provided. At 1104, a first template layer is deposited above the substrate. For example, the lower template layer 604 (shown in FIG. 6) may be disposed on the substrate 602. As described above, the lower template layer imparts a predetermined textured pattern on one or more layers deposited above the template layer in order to scatter and/or reflect light back into a semiconductor layer stack deposited above the lower template layer.

At 1106, a bottom electrode is provided above the lower template layer. For example, the bottom electrode 606 (shown in FIG. 6) may be deposited on the lower template layer 604 (shown in FIG. 6). At 1108, at least one semiconductor layer or semiconductor layer stack, such as the lower semiconductor layer stack 608 (shown in FIG. 6) is deposited above the bottom electrode 606.

At 1110, a second template layer is provided above the lower semiconductor layer stack. For example, the upper template layer 614 (shown in FIG. 6) may be deposited on the lower semiconductor layer stack 608 (shown in FIG. 6). At 1112, an upper semiconductor layer stack is deposited on the second template layer. In one embodiment, the upper semiconductor layer stack 616 (shown in FIG. 6) is provided above the upper template layer 614.

At 1114, a top electrode is provided above the second semiconductor layer stack. In one embodiment, the top electrode 618 (shown in FIG. 6) is deposited on the upper semiconductor layer stack 616 (shown in FIG. 6). At 1116, an adhesive is placed on the top electrode and a cover sheet is provided on the adhesive to enclose the PV device. For example, the adhesive layer 620 (shown in FIG. 6) and cover sheet 622 (shown in FIG. 6) may be provided above the top electrode 618.

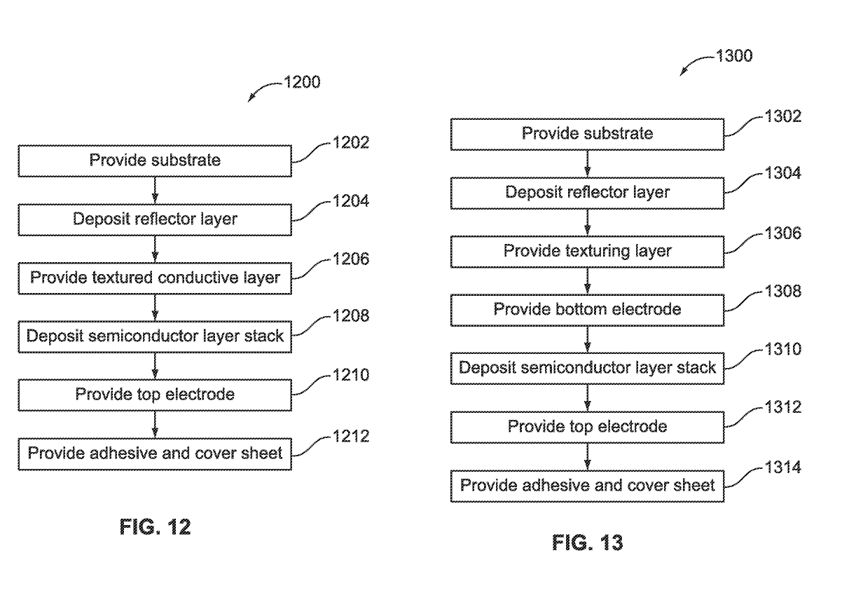

FIG. 12 is a flowchart of a method 1200 for providing a PV device with a textured electrode in accordance with one embodiment. At 1202, a substrate is provided. For example, the substrate 702 (shown in FIG. 7) may be provided. At 1204, a reflector layer is deposited on the substrate. For example, the reflector layer 706 may be deposited above the substrate 702. At 1206, a textured conductive layer is deposited above the reflector layer. In one embodiment, the textured conductive layer 708 is deposited on the reflector layer 706 to form a textured bottom electrode.

At 1208, one or more semiconductor layer stacks, such as the semiconductor layer stack 710 (shown in FIG. 7) is deposited above the textured bottom electrode 704 (shown in FIG. 7) that includes the reflector layer 706 (shown in FIG. 7) and the textured conductive layer 706 (shown in FIG. 7).

At 1210, a top electrode is provided above the semiconductor layer stack. In one embodiment, the top electrode 712 (shown in FIG. 7) is deposited on the semiconductor layer stack 710 (shown in FIG. 7). At 1212, an adhesive is placed on the top electrode and a cover sheet is provided on the adhesive to enclose the PV device. For example, the adhesive layer 714 (shown in FIG. 7) and cover sheet 716 (shown in FIG. 7) may be provided above the top electrode 712.

FIG. 13 is a flowchart of a method 1300 for providing a PV device with a textured template layer formed of discrete layers in accordance with one embodiment. At 1302, a substrate is provided. For example, the substrate 802 (shown in FIG. 8) may be provided. At 1304, a reflector layer is deposited above the substrate. For example, the reflector layer 806 (shown in FIG. 8) may be deposited on the substrate 802. At 1306, a texturing layer is provided on the reflector layer. In one embodiment, the texturing layer 808 (shown in FIG. 8) is deposited on the reflector layer 806. The reflector layer 806 and the texturing layer 808 form discrete layers of a textured template layer that reflects light back into a semiconductor layer stack.

At 1308, a bottom electrode is provided above the texturing layer and/or the reflector layer. For example, the bottom electrode 810 (shown in FIG. 8) may be deposited on the texturing layer 808 (shown in FIG. 8) and/or the reflector layer 806 (shown in FIG. 8), as described above. At 1310, one or more semiconductor layer stacks, such as the semiconductor layer stack 814 (shown in FIG. 8) is deposited above the bottom electrode 810.

At 1312, a top electrode is provided above the semiconductor layer stack. In one embodiment, the top electrode 816 (shown in FIG. 8) is deposited on the semiconductor layer stack 814 (shown in FIG. 8). At 1314, an adhesive is placed on the top electrode and a cover sheet is provided on the adhesive to enclose the PV device. For example, the adhesive layer 818 (shown in FIG. 8) and cover sheet 820 (shown in FIG. 8) may be provided above the top electrode 816.

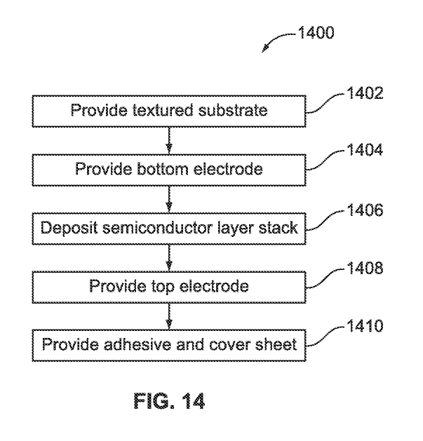

FIG. 14 is a flowchart of a method 1400 for providing a PV device with a textured substrate in accordance with one embodiment. At 1402, a textured substrate is provided. For example, the substrate 902 (shown in FIG. 9) may be provided. As described above, the substrate 902 may be etched to provide a textured surface that is imparted on additional layers deposited onto the substrate 902.

At 1404, a bottom electrode is provided above the textured substrate. For example, the bottom electrode 904 (shown in FIG. 9) may be deposited on the textured substrate 902 (shown in FIG. 9). At 1406, one or more semiconductor layer stacks, such as the semiconductor layer stack 910 (shown in FIG. 9) is deposited above the bottom electrode 904.

At 1408, a top electrode is provided above the semiconductor layer stack. In one embodiment, the top electrode 912 (shown in FIG. 9) is deposited on the semiconductor layer stack 910 (shown in FIG. 9). At 1410, an adhesive is placed on the top electrode and a cover sheet is provided on the adhesive to enclose the PV device. For example, the adhesive layer 914 (shown in FIG. 9) and cover sheet 916 (shown in FIG. 9) may be provided above the top electrode 912.

The methods 1000, 1100, 1200, 1300, 1400 describe various embodiments of providing or creating a PV device that includes one or more textured layers that assist in reflecting light back into semiconductor layer stacks. Additional operations, methods, processes, and/or steps may be performed in conjunction with the operations set forth in the methods 1000, 1100, 1200, 1300, 1400 to manufacture PV devices. For example, depending on the PV device that is to be manufactured one or more layers that are provided in the methods 1000, 1100, 1200, 1300, 1400 may need to be etched to electrically isolate or otherwise separate the layers in adjacent PV cells of the PV device.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

1. A photovoltaic cell comprising:
a substrate;
a semiconductor layer stack disposed above the substrate;
a reflective and conductive electrode layer between the substrate and the semiconductor layer stack; and
a textured template layer between the substrate and the electrode layer, the template layer having an undulating upper surface that imparts a predetermined shape to the electrode layer, the electrode layer reflecting light back into the semiconductor layer stack based on the predetermined shape.

2. The photovoltaic cell of claim 1, wherein the template layer includes an array of one or more of peak structures, valley structures, or rounded structures that provide the undulating upper surface of the template layer.

3. The photovoltaic cell of claim 1, wherein the undulating surface of the template layer is defined by structures having one or more of a predetermined pitch between adjacent structures, a predetermined base width, or a predetermined height that the structures protrude away from the substrate or are recessed into the template layer.

4. The photovoltaic cell of claim 3, wherein one or more of the pitch, the base width, or the height of the structures is based on a crystalline structure of the semiconductor layer stack.

5. The photovoltaic cell of claim 3, wherein one or more of the pitch, the base width, or the height of the structures is based on a wavelength of light that is reflected back into the semiconductor layer stack.

6. The photovoltaic cell of claim 1, wherein the template layer is a lower template layer and the semiconductor layer stack is a lower semiconductor layer stack, further comprising an upper semiconductor layer stack between the top electrode and the lower semiconductor layer stack and an upper template layer between the lower semiconductor layer stack and the upper semiconductor layer stack.

7. The photovoltaic cell of claim 1, wherein the template layer includes a plurality of discrete island bodies separated from each other and disposed between the substrate and the bottom electrode.

8. A photovoltaic cell comprising:
a substrate;
a semiconductor layer stack disposed above the substrate; and
an electrode layer disposed between the substrate and the semiconductor layer stack, the electrode layer including a reflector layer and a light transmissive conductive layer, the conductive layer including an undulating upper surface that scatters incident light to the reflector layer, the reflector layer reflecting the light back into the semiconductor layer stack after being scattered by the conductive layer.

9. The photovoltaic cell of claim 8, wherein the conductive layer of includes an array of one or more of peak structures, valley structures, or rounded structures that provide the undulating upper surface.

10. The photovoltaic cell of claim 8, wherein the undulating surface of is defined by structures having one or more of a predetermined pitch between adjacent structures, a predetermined base width, or a predetermined height that the structures protrude away from the substrate or are recessed into the conductive layer.

11. The photovoltaic cell of claim 10, wherein one or more of the pitch, the base width, or the height of the structures is based on a crystalline structure of the semiconductor layer stack.

12. The photovoltaic cell of claim 10, wherein one or more of the pitch, the base width, or the height of the structures is based on a wavelength of light that is reflected by the reflector layer back into the semiconductor layer stack.

13. A photovoltaic cell comprising:
a substrate having a predetermined undulating upper surface;
a semiconductor layer stack disposed above the substrate; and
a reflective and conductive electrode layer between the upper surface of the substrate and the semiconductor layer stack, wherein the undulating upper surface of the substrate imparts a predetermined shape to the electrode layer, the electrode layer reflecting light back into the semiconductor layer stack based on the predetermined shape.

14. The photovoltaic cell of claim 13, wherein the substrate includes an array of one or more of peak structures, valley structures, or rounded structures that provide the undulating upper surface of the substrate.

15. The photovoltaic cell of claim 13, wherein the undulating surface of the substrate is defined by structures having one or more of a predetermined pitch between adjacent structures, a predetermined base width, or a predetermined height that the structures protrude away from the substrate or are recessed into the substrate.

16. The photovoltaic cell of claim 15, wherein one or more of the pitch, the base width, or the height of the structures is based on a crystalline structure of the semiconductor layer stack.

17. The photovoltaic cell of claim 16, wherein the one or more of the pitch, the base width, or the height of the structures is decreased if the semiconductor layer stack includes a microcrystalline layer and is increased if the semiconductor layer stack includes an amorphous layer.

18. The photovoltaic cell of claim 15, wherein one or more of the pitch, the base width, or the height of the structures is based on a wavelength of light that is reflected back into the semiconductor layer stack.

19. The photovoltaic cell of claim 13, wherein the semiconductor layer stack has a shape that is based on the upper surface of the substrate.

20. The photovoltaic cell of claim 1, wherein the template layer comprises an etched layer of amorphous silicon.
